(19) United States
(12) Patent Application Publication
(10) Pub. No.: US 2009/0219739 A1
(43) Pub. Date: Sep. 3, 2009

(54) Range-Matching Cell and Content Addressable Memories Using the Same

(75) Inventors: Young-Deok Kim, Seoul (KR); Deog-Kyoon Jeong, Seoul (KR)

Correspondence Address: HARNESS, DICKEY & PIERCE, P.L.C., P.O. BOX 828, BLOOMFIELD HILLS, MI, 48303, US

(73) Assignees: SEOUL NATIONAL UNIVERSITY INDUSTRY FOUNDATION, SEOUL (KR); GLONET SYSTEMS INC., SEOUL (KR)

(21) Appl. No.: 12/223,552

(22) PCT Filed: Sep. 15, 2006
(86) PCT No.: PCT/KR2006/003679

§ 371 Date: Nov. 17, 2008

(30) Foreign Application Priority Data
Feb. 3, 2006 (KR) 10-2006-0010766

(51) Int. Cl. G11C 15/04; G11C 15/00

(52) U.S. Cl. 365/49.17

(57) ABSTRACT

A range-matching cell (RMC) includes bit lines (BL); a word line (WL); a match line (ML); search lines (SL); a memory cell (100); a first comparator (110) connected to the memory cell; a second comparator (120) connected to the first comparator, a ground voltage and a predetermined voltage. The comparators conduct a comparing operation in responsive to operator data. Instead of the conventional TCAMs employing 0, 1, and X (don't care) bit, a CAM utilizing the RMC can conduct a comparing operation with less memory by storing the operator data 0 and 1 in advance. Accordingly, memory-use efficiency can be increased.

### TECHNICAL FIELD

The present invention relates to a Content Addressable Memory (CAM), and more particularly, to a CAM that enables a range search by employing a range-matching cell (RMC).

### BACKGROUND ART

In a random access memory (RAM) or a read-only memory (ROM), by designating addresses of specific locations in its internal memory cell arrays, data corresponding to the designated addresses are outputted. On the other hand, a Content Addressable Memory (CAM) receives data from outside and compares the received data with data stored therein to judge whether or not these data match each other, and then outputs matched addresses.

Each memory cell in such a CAM has a comparing logic. Data inputted into the CAM are compared with data stored in all cells of the CAM to output matched addresses. The CAM is widely utilized in applications that need to quickly search patterns, lists, image data and the like. Such CAMs are classified into a binary CAM and a Ternary CAM (TCAM).

The binary CAM includes a RAM cell for storing one of two logic states of “1” and “0”. Further, this binary CAM has a comparison circuit that compares data (hereinafter, referred to as “searched data”) provided from outside with data (hereinafter, referred to as “stored data”) stored in the RAM cell and then sets, if the searched data matches any of the stored data, a corresponding match line to a designated logic state. Examples of such a binary CAM are disclosed in U.S. Pat. Nos. 4,646,271 and 5,490,102.

Meanwhile, the TCAM can store three logic states, i.e., “1”, “0” and “X (don't care)”. This TCAM is known as one of the most efficient schemes for packet classification in a high speed router. One example of such a TCAM is found in U.S. Pat. No. 5,319,590.

As known in the art, there is proposed an Open Systems Interconnection (OSI) 7 layer, in which a router that supports above layer 3 needs a function of comparing sizes of an input value and a stored value, as well as an extra function of comparing to judge whether the both values are the same or not. In other words, in Ethernet packet, Type of Service (ToS) field (layer 3) and Transmission Control Protocol (TCP) port field (layer 4) should be compared in size for packet classification. For this, the conventional TCAM cell serves to store “1”, “0” and “X” in advance, and then compare an input value with the stored values to judge their sameness.

However, this operation made by the TCAM is efficient for identifying Internet Protocol (IP) in packet classification but has a weak structure for port number field where a size comparison needs to be conducted. For example, if a search is performed within a greater range than 1024 for 16-bit TCP port field, the following six cases should be stored in memory where TCAM is adopted.
0000_{—}01XX_XXXX_XXXX, 0000_{—}1XXX_XXXX_XXXX,
0001_XXXX_XXXX_XXXX, 001X_XXXX_XXXX_XXXX,
01XX_XXXX_XXXX_XXXX, 1XXX_XXXX_XXXX_XXXX

In addition, if a search is done within such a range that a source port number and a destination port number are greater than “1”, respectively, in the worst case, 900 (30×30) storage capacities are required. This hinders the efficient use of the storage capacity of TCAM, which in turn lowers memory efficiency. Another drawback is that there exists substantial inefficiency when the search range is updated.

### DISCLOSURE OF INVENTION

### Technical Problem

Therefore, an object of the present invention is to provide a range-matching cell (RMC) and a CAM using the same, which enables the efficient use of memory by providing a size comparing operator when a range search is conducted by a size comparison.

### Technical Solution

In accordance with the present invention, there is provided a range-matching cell including: bit lines; a word line; a memory cell; a match line; search lines; a first comparator connected to the memory cell; and a second comparator connected to the match line, the search lines, a ground voltage and a predetermined voltage.

Preferably, the first comparator includes: (a) a first transistor connected in series to the match line; and (b) a second transistor connected to the memory cell, the search lines and the first transistor. The first transistor becomes turned on or off in response to the second transistor, and the second transistor becomes turned on or off in response to the stored data in the memory cell and searched data transmitted via the search lines.

Preferably, the second comparator connects the match line to the ground voltage or the predetermined voltage in response to the searched data and operator data when the first transistor is turned off. The operator data including a first and a second operator data selected from logic values of 0 and 1.

Preferably, the first operator data (OP1) and the second operator data (OP2) are determined as follows:
(a) If a search range of searched data is greater than or equal to that of stored data, (OP1, OP2)=(1, 0);
(b) If a search range of searched data is less than or equal to that of stored data, (OP1, OP2)=(0, 1); and
(c) If a search range of searched data is equal to that of stored data, (OP1, OP2)=(0, 0).

### Advantageous Effects

Instead of the conventional TCAMs employing large memory for using 0, 1, and X (don't care) bit, the CAM in accordance with the present invention can conduct a comparing operation with less memory by storing the operator data in advance. Thus, memory-use efficiency can be increased by more than 2.5 times, and, furthermore, the updating operation can be performed more efficiently.

### BRIEF DESCRIPTION OF THE DRAWINGS

The above and other objects and features of the present invention will become apparent from the following description of preferred embodiments, given in conjunction with the accompanying drawings, in which:

FIG. 1 is a circuit diagram of a range-matching cell in accordance with a preferred embodiment of the present invention;

FIG. 2 is a circuit diagram of a range-matching cell in accordance with another embodiment of the present invention;

FIG. 3 is a circuit diagram of a range-matching cell in accordance with still another embodiment of the present invention;

FIG. 4 is a circuit diagram of a range-matching cell in accordance with still another embodiment of the present invention;

FIG. 5 is a matching table describing an operation of each of the range-matching cells of FIGS. 1 to 4;

FIG. 6 shows an example of a CAM using a range-matching cell that is implemented with 4-bit;

FIG. 7 shows an operation of the CAM when (OP1, OP2) is “Greater than or Equal to (GE)”, the searched data SD are (1, 1, 0, 0), and the stored data SRD are (1, 0, 1, 0);

FIG. 8 shows an operation of the CAM when (OP1, OP2) is “Less than or Equal to (LE)”, the SD and the SRD are identical to those in FIG. 7; and

FIG. 9 shows an operation of the CAM when (OP1, OP2) is “Equal to (EQ)”, the SD and the SRD are identical to those in FIG. 7.

### BEST MODE FOR CARRYING OUT THE INVENTION

Hereinafter, a range-matching cell (RMC) and a CAM using the same in accordance with the present invention will be described in detail with reference to the accompanying drawings. It should be noted that like reference numerals designate like elements through the whole drawings.

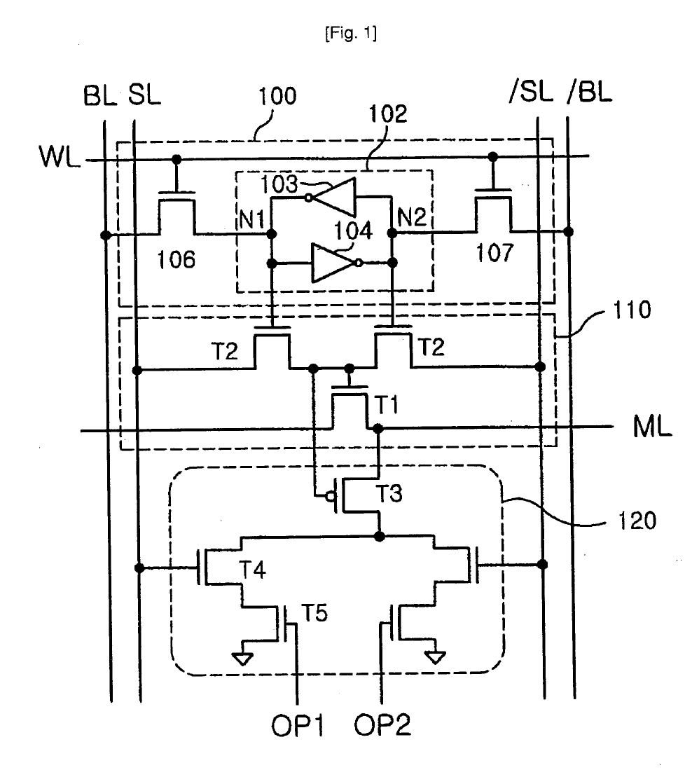

Referring to FIG. 1, there is shown a circuit diagram of a range-matching cell in accordance with a preferred embodiment of the present invention. As shown therein, the inventive range-matching cell includes a pair of a bit line BL and a complementary bit line /BL, a word line WL, a memory cell 100, a match line ML, a pair of a search line SL and a complementary search line /SL, a first comparator 110, and a second comparator 120.

The memory cell 100 is provided with pass gates 106 and 107, and a storing unit 102 for storing data and its complementary data.

The pass gate 106 is provided between the bit lines BL and the storing unit 102. On the other hand, the pass gate 107 is provided between the complementary bit line /BL and the storing unit 102. The pass gates 106 and 107 transmit data inputted via the pair of bit lines BL and /BL to the storing unit 102.

More specifically, the storing unit 102 includes cross-coupled inverters 103 and 104. The pass gates 106 and 107 may be MOSFETs.

The first comparator 110 is connected to the memory cell 100, the pair of search lines SL and /SL, and the match line ML. The first comparator 110 includes a first transistor T1 and two second transistors T2. The first transistor T1 is connected in series to the match line ML. And, the second transistors T2 are interposed between the first transistor T1 and the storing unit 102. Additionally, the second transistors T2 are connected to the search lines SL and /SL, respectively, and have gates connected to the storing unit 102. Meanwhile, the first transistor T1 is turned on if stored data SRD matches searched data SD, and, if not, the first transistor T1 is turned off. All of the first and the second transistors T1 and T2 may be MOSFETs.

The second comparator 120 serves to connect the match line ML to a reference voltage (a ground voltage) in response to searched data transmitted via the search line SL and stored operator data OP1 and OP2 when the first transistor T1 is off. More specifically, the second comparator 120 connects the match line ML to the reference voltage if the searched data matches the operator data OP1, OP2, respectively, and, if not, connects the match line ML to the predetermined voltage.

The second comparator 120 includes a third transistor T3, two fourth transistors T4 and two fifth transistors T5. The transistors T3, T4 and T5 serve to connect the match line ML in series to the reference voltage. In addition, the third transistor T3 connects the match line ML to the fourth transistors T4, and has a gate connected to the first comparator 110. The fourth transistor T4 connects the third transistor T3 to the fifth transistor T5, and has its gate connected to the search line SL. The fifth transistors T5 connect the fourth transistors T4 to the reference voltage and, have gates connected to the operator data OP1 and OP2, respectively.

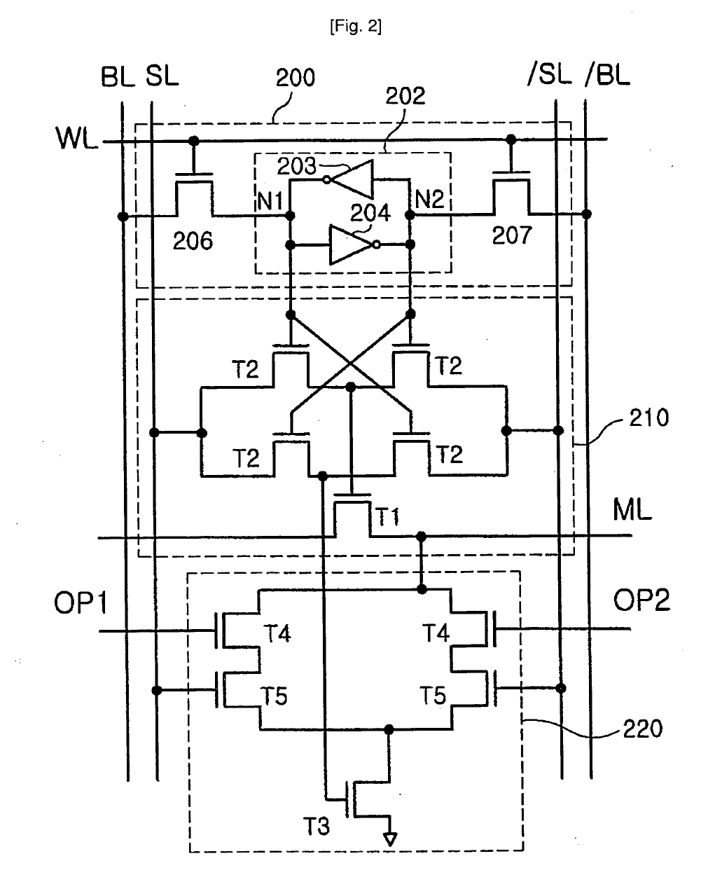

Referring to FIG. 2, there is provided a circuit diagram of a range-matching cell in accordance with another embodiment of the present invention. In this embodiment, the dynamic range-matching cell is implemented with NMOS transistors only, instead of NMOS and PMOS transistors as in FIG. 1. Since a NMOS transistor occupies a smaller area than that of a PMOS transistor, the implementation of more integrated and small-sized circuit is possible.

Reference numerals 200 to 220 in FIG. 2 are substantially identical to the reference numerals 100 to 120 in FIG. 1 respectively except that: a third transistor T3 in FIG. 2 is NMOS-type and arranged below fourth and fifth transistors T4, T5, while the third transistor T3 in FIG. 1 is PMOS-type and disposed above the fourth and the fifth transistors T4, T5; and the third transistor T3 in FIG. 2 is connected to a reference voltage, and the forth transistors T4 are connected to operator data OP1, OP2, respectively. Detailed descriptions therefore will be omitted for the sake of simplicity.

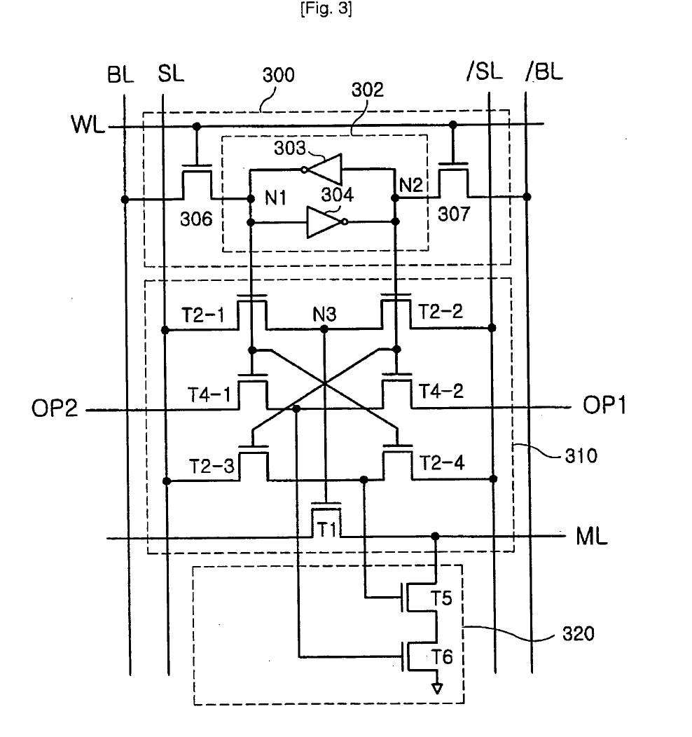

FIG. 3 shows a circuit diagram of a range-matching cell in accordance with further another embodiment of the present invention. Reference numerals 300 to 320 in FIG. 3 are substantially identical to reference numerals 200-220 in FIG. 2, respectively. However, in this case, operator data OP1 and OP2 are applied to a first comparator 310 in response to stored data at N1 and N2. Accordingly, it is possible to save at least one transistor in comparison with the circuit diagram of FIG. 2.

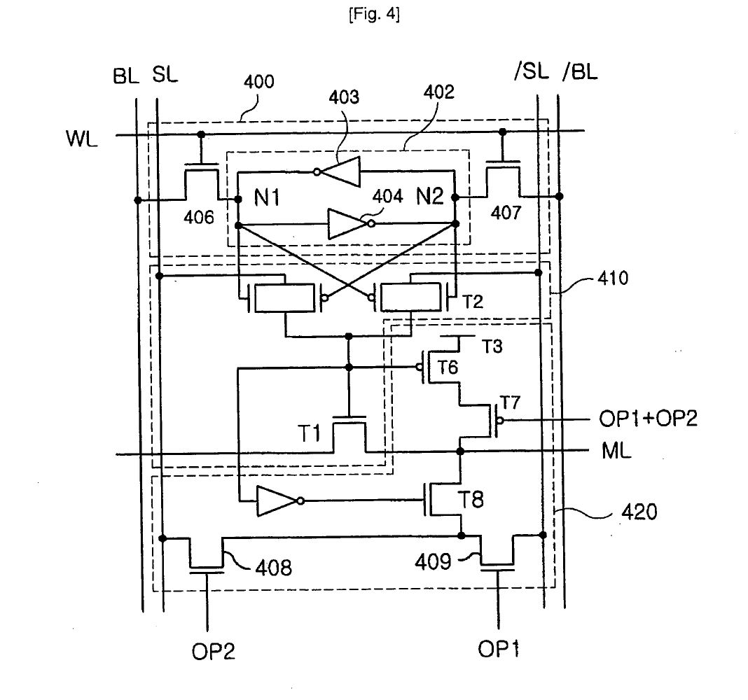

FIG. 4 shows a circuit diagram of a range-matching cell in accordance with still another embodiment of the present invention. In FIG. 4, the range-matching cell includes a pair of a bit line BL and a complementary bit line /BL, a word line WL, a memory cell 400, a match line ML, a pair of a search line SL and a complementary search line /SL, a first comparator 410 and a second comparator 420.

The memory cell 400 is provided with a couple of pass gates 406 and 407, and a storing unit 402 for storing data and its complementary data.

The pass gate 406 is coupled to the bit line BL, and the pass gate 407 is coupled to the bit line /BL. The pass gates 406 and 407 are also coupled to the storing unit 402, and deliver data received via the bit lines BL and /BL to the storing unit 402.

Specifically, the storing unit 402 includes cross-coupled inverters 403 and 404, and is connected via the pass gate 406 to the bit line BL. And, the pass gate 407 connects the storing unit 402 to the complementary bit line /BL. These pass gates 406 and 407 may be implemented with MOSFETs.

The first comparator 410 includes a first transistor T1 and two second transistors T2. Moreover, the first comparator 410 is connected to the memory cell 400, the search lines SL and /SL, and the match line ML.

Meanwhile, the first transistor T1 is turned on if stored data SRD matches searched data SD, and, if not, the first transistor T1 is turned off. Additionally, the first transistor T1 is coupled in series with the match line ML. Each second transistor T2 connects the search lines SL and /SL, respectively, to the first transistor T1, and has a gate connected to the storing unit 402.

The second comparator 420 includes a sixth transistor T6, a seventh transistor T7, an eighth transistor T8, a pass gate 408 and a pass gate 409. The second comparator 420 serves to connect the predetermined voltage in series to the match line ML.

The sixth transistor T6 is connected via its gate to the first comparator 410 to receive an output result from the first comparator 410.

The seventh transistor T7 is interposed between the sixth transistor T6 and the match line ML to receive an OR-operated result of a first operator data OP1 and a second operator data OP2.

The eighth transistor T8 is connected to the match line ML, and the pass gates 408, 409. Such an eighth transistor T8 is coupled via its gate with an inverted output of the first comparator 410.

The pass gate 408 is connected to the search line SL and the eighth transistor T8. The pass gate 408 is connected via its gate to the second operator data OP2.

The pass gate 409 is connected to the complementary search line /BL and the eighth transistor T8. The pass gate 409 is connected via its gate to the first operator data OP1.

Meanwhile, when the first transistor T1 is turned off, the second comparator 420 connects the match line ML to a ground voltage or a predetermined voltage in response to searched data sent via the search line SL and stored operator data OP1, OP2. The second comparator 420 connects the match line ML to a ground voltage if the searched data matches the operator data OP1, and, if not, connects the match line ML to a predetermined voltage.

The range-matching cells as shown in FIGS. 1 to 3 are dynamic-type, while the range-matching cell in FIG. 4 is static-type. In the dynamic-type, the match line should be precharged in advance, differently from the static-type; however, the number of transistors implemented therein is less than that of the static-type. And, as can be seen in FIGS. 1 and 2, the range of cells is smaller than that of the static-type, but power consumption is greater than that of the static-type due to such precharging. Conversely, as can be seen in FIG. 4, the size of cell is greater than that of dynamic-type, but no precharging is needed and thus power consumption can be reduced.

Reference numerals OP1 and OP2 as shown in FIGS. 1 to 4 denote size operators. A logic value for each operator dedicated in the embodiments is defined as follows. That is, if an operator is “Greater than or Equal to (GE)”, (OP1, OP2)=(1, 0). If an operator is “Less than or Equal to (LE)”, (OP1, OP2)=(0, 1). Also, if an operator is “Equal to (EQ)”, (OP1, OP2)=(0, 0).

Hereinafter, an operation of the range-matching cell in accordance with the embodiments of the invention will be explained in detail with reference to FIGS. 1 to 5.

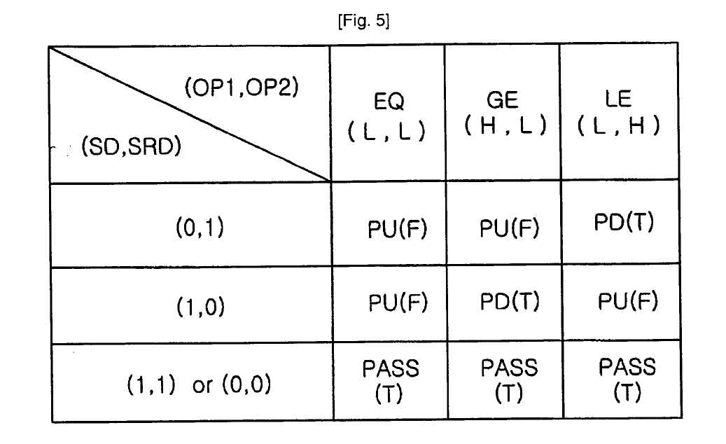

In FIG. 5, OP1 and OP2 correspond to operator data 1 and 2, respectively; Stored Rule Data (SRD) indicates data stored in storing unit; and, Searched Data (SD) implies data sent from search lines SL and /SL.

As shown in FIG. 1, first of all, data and its complementary data are sent via the pair of bit lines BL and /BL to be stored in the memory cell 100. When the word line WL is activated to a high level, the pass gates 106 and 107 are turned on.

As set forth above, the pass gates 106 and 107 are of the NMOS transistors whose gates are coupled with the word line WL. When the pass gates 106 and 107 are turned on, the data and complementary data sent via the bit lines BL and /BL are stored in the storing unit 102 having the cross-coupled inverters 103 and 104, and then the word line WL becomes inactivated.

Next, when the match line ML is precharged to a high level, the searched data SD and its complementary searched data /SD are sent via the search lines SL and /SL, respectively.

It is assumed, as shown in FIG. 5, that a search range of the searched data SD is greater than that of the stored data SRD. In this case, (OP1, OP2) is “Greater than or Equal to (GE)”, namely, (1, 0). (SD, SRD) is (1, 1).

At this time, a logic one (1) is stored at a node N1 of the storing unit 102, whereas a logic zero (0) is stored at a node N2 of the storing unit 102. And, since the logic one (1) at the node N1 is inputted to the gate of the left one of the second transistors T2 and a logic one (1) is sent from the search line SL, so that the left one of the second transistors T2 becomes turned on. As a result, the first transistor T1 becomes turned on. In this case, the match line ML becomes a PASS state regardless of the operation of the second comparator 120.

Meanwhile, it is assumed that (OP1, OP2) is (1, 0) and (SD, SRD) is (1, 0).

At this time, a logic zero (0) is stored at a node N1, whereas a logic one (1) is stored at a node N2. And, since the logic one (1) at the node N2 is inputted to the gate of the right one of the second transistors T2 and a logic zero (0) is sent from the complementary search line /SL, so that the right one of the second transistors T2 becomes turned off. As a result, the first transistor T1 becomes turned off.

In such a case, the third transistor T3 in the second comparator 120 becomes turned on. And, since the searched data SD is a logic one (1) and (OP1, OP2) is (1, 0), the fourth and the fifth transistors T4 and T5 become turned on, respectively. Therefore, all of the transistors T3, T4 and T5 become turned on, thereby connecting the match line ML therethrough to the ground voltage. Here, the ground voltage is coupled to the fifth transistor T5. As a result, the match line ML becomes a Pull-Down (PD) state.

Also, with respect to remaining conditions as given in FIG. 5, the state of the match line ML can also be deduced in the same way. Even though the operation of the range-matching cell is described with reference to FIGS. 1 and 3, the same result can be also deduced with respect to FIGS. 2 and 4.

Hereinafter, an operation of the range-matching cell of FIG. 2 will be explained with reference to FIG. 5.

It is assumed, as shown in FIG. 5, (OP1, OP2) is (1, 0) and (SD, SRD) is (1, 1).

At this time, a logic one (1) is stored at a node N1, whereas a logic zero (0) is stored at a node N2. And, in response to the logic values at the nodes N1 and N2, a transistor T2-1 becomes turned on whereas a transistor T2-2 becomes turned off. Accordingly, a node N3 becomes high by a logic one (1) of a search line SL, so that a transistor T1 becomes turned on. Meanwhile, a transistor T4-1 becomes turned off in response to the values of the node Ni and an operator data OP2, so that a transistor T6 becomes turned off. As a result, the match line ML becomes a PASS state.

And, in case that (OP1, OP2) is (1, 0) and (SD, SRD) is (1, 0), a logic zero (0) is stored at a node N1 whereas a logic one (1) is stored at a node N2. In response to the values of the search lines and the values at the nodes N1 and N2, the transistors T2-1 and T2-2 become turned off, and the transistor T1 becomes turned off. However, a transistor T4-2 becomes turned on in response to values of the node N2 and an operator data OP1, so that a transistor T6 becomes turned on. And, a transistor T2-3 becomes turned on in response to the values of the node N2 and the search line SL, so that the transistor T5 becomes turned on. As a result, the match line ML becomes a Pull-Down (PD) state.

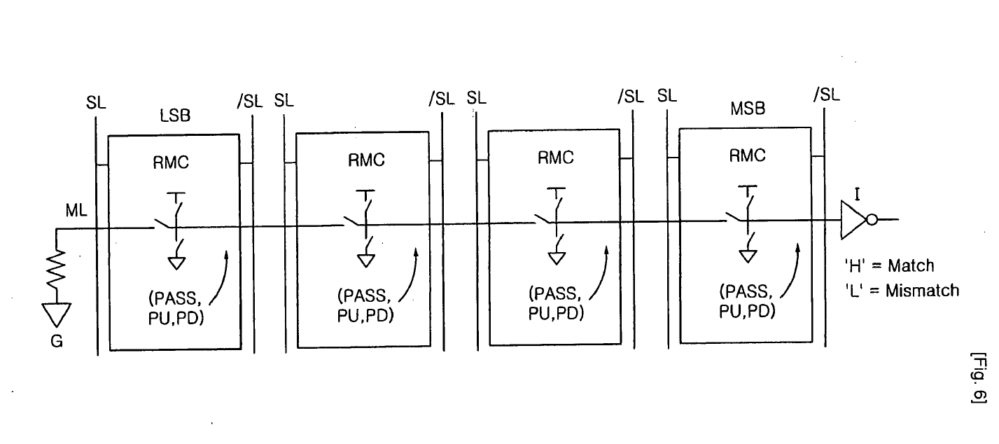

FIG. 6 shows an example of a CAM using the range-matching cell that is implemented with 4-bit. In the CAM, an inverter I is connected to a Most Significant Bit (MSB) cell, while a ground voltage G is connected to a Least Significant Bit (LSB) cell. An operation of the CAM using such range-matching cell will now be described below in detail with reference to FIGS. 6 to 9.

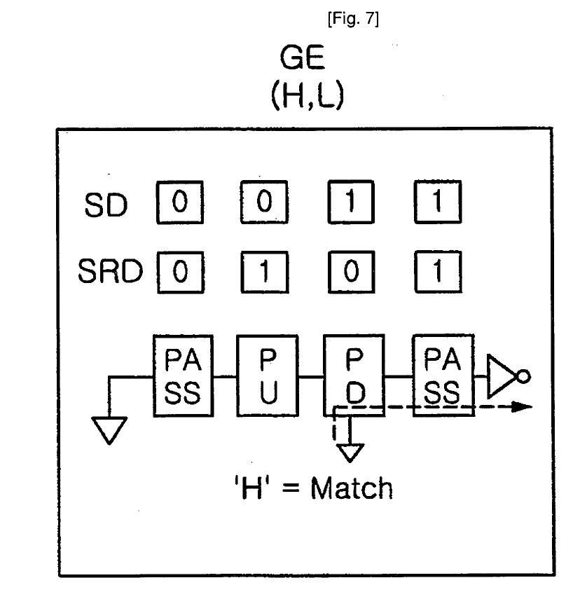

It is now assumed that a search range of the searched data SD is greater than that of the stored data SRD. (OP1, OP2) is “Greater than or Equal to (GE)”, namely, (1, 0); the searched data SD are (1, 1, 0, 0); and the stored data SRD are (1, 0, 1, 0). FIG. 7 shows an operation of the CAM under the above condition (FIGS. 7 to 9 show that the values of SD and SRD are arranged in order from right side).

For MSB, that is, a first bit (see, FIGS. 6 and 7), since the searched data SD and the stored data SRD are identical logic one (1), so that the match line ML becomes in the PASS state (see, FIG. 5). Meanwhile, for the second bit, since the searched data SD is logic one (1) and the stored data SRD is logic zero (0), so that the match line ML becomes in the Pull-Down (PD) state (see, FIG. 5).

As a result, since the inverter I connected to the MSB cell becomes connected via the pull-downed match line ML to the ground voltage of the second bit cell, the CAM outputs a logical ‘H (Match)’.

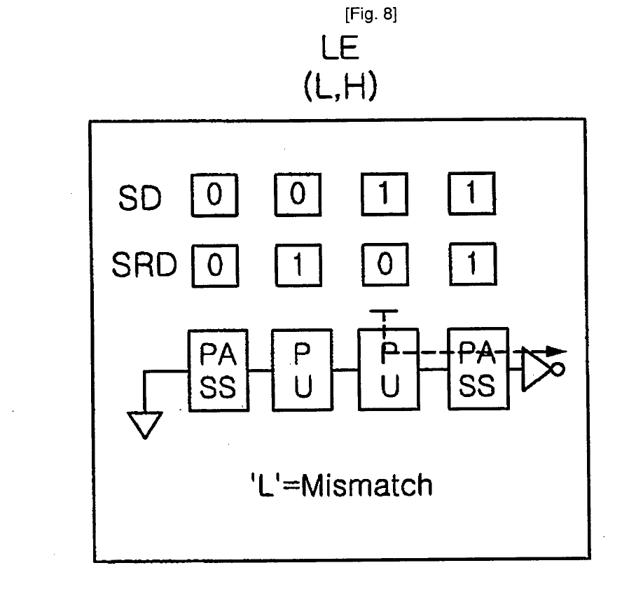

Subsequently, it is assumed that a search range of the searched data SD is less than that of the stored data SRD. (OP1, OP2) is “Less than or Equal to (LE)”, namely, (0, 1); the searched data SD are (1, 1, 0, 0); and the stored data SRD are (1, 0, 1, 0). FIG. 8 shows an operation of the CAM under the above condition.

For MSB as shown in FIG. 8, since the searched data SD and the stored data SRD are identical to logic one (1), the match line ML becomes the PASS state (see, FIG. 5). Meanwhile, for the second bit, since the searched data SD is logic one (1) and the stored data SRD is logic zero (0), the match line ML becomes in the Pull-Up (PU) state (see, FIG. 5).

In the PU state, the match line ML becomes initially precharged. Accordingly, the precharged match line ML is connected to the inverter I, and the CAM outputs a logical ‘L (Mismatch)’.

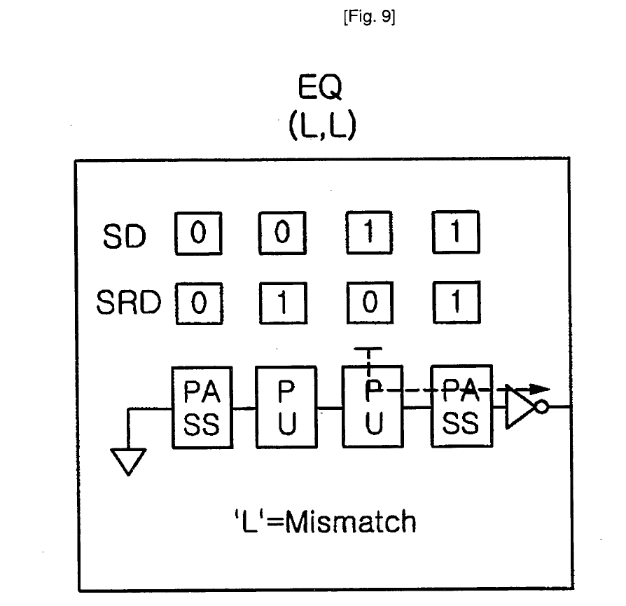

Further, it is assumed that a search range of the searched data SD is equal to that of the stored data SRD. (OP1, OP2) is “Equal to (EQ)”, namely, (0, 0); the searched data SD are (1, 1, 0, 0); and the stored data SRD are (1, 0, 1, 0). FIG. 9 shows an operation of the CAM under the above condition.

For MSB shown in FIG. 9, since the searched data SD and the stored data SRD are identical logic one (1), the match line ML becomes in the PASS state (see, FIG. 5). Meanwhile, for the second bit, since the searched data SD is logic one (1) and the stored data SRD is logic zero (0), the match line ML becomes in the Pull-Up (PU) state (see, FIG. 5).

In the PU state, the match line ML becomes initially precharged. Accordingly, the precharged match line ML becomes connected to the inverter I, and the CAM outputs a logical ‘L (Mismatch)’.

As described above, instead of the conventional TCAMs employing large memory for using 0, 1, and X (don't care) bit, the CAM in accordance with the present invention can conduct a comparing operation with less memory by storing the operator data in advance. Thus, memory-use efficiency can be increased by more than 2.5 times, and, furthermore, the updating operation can be performed more efficiently.

While the invention has been shown and described with respect to the preferred embodiments, it will be understood by those skilled in the art that various changes and modification may be made without departing from the scope of the invention as defined in the following claims.

1. A range-matching cell comprising:
a pair of a bit line and a complementary bit line;
a word line;
a memory cell connected to the word line and the bit lines for storing data transmitted via the bit lines when the word line is activated;
a match line;
a pair of a search line and a complementary search line;
a first transistor connected in series to the match line;
a first comparator connected to the memory cell, the match line and the search lines for controlling on or off the first transistor in response to the stored data in the memory cell and searched data transmitted via the search lines; and
a second comparator for connecting the match line to a ground voltage or a predetermined voltage based on the searched data and a stored operator data when the first transistor is turned off, wherein the operator data including logic values of 0 and 1.

2. The range-matching cell of claim 1, wherein the memory cell includes:
storing means for storing the data; and
connecting means for coupling the bit lines to the storing means in order to provide the stored data received by the bit lines to the storing means.

3. The range-matching cell of claim 2, wherein the storing means includes a cross-coupled inverter.

4. The range-matching cell of claim 2, wherein connecting means includes a first and a second pass gate, wherein the pass gates are connected to the word line.

5. The range-matching cell of claim 1, wherein the first comparator turns on the first transistor if the stored data matches the searched data, and, if not, turns off the first transistor.

6. The range-matching cell of claim 1, wherein the second comparator connects the match line to the ground voltage if the searched data matches the operator data, and, if not, the second comparator connects the match line to the predetermined voltage.

7. The range-matching cell of claim 2, wherein the first comparator is provided with a second transistor for connecting the search line to the first transistor, and the second transistor has a gate connected to the storing means.

8. The range-matching cell of claim 1,
wherein the second comparator is provided with a third, a fourth and a fifth transistor for connecting the match line in series to the ground voltage,
wherein the third transistor connects the match line to the fourth transistor and has a gate connected to the first comparator;
wherein the fourth transistor connects the third transistor to the fifth transistor and has a gate connected to the search line; and
wherein the fifth transistor connects the fourth transistor to the ground voltage and has a gate for receiving the operator data.

9. The range-matching cell of claim 1, wherein the second comparator includes:
a sixth and a seven transistor for connecting the predetermined voltage in series to the match line;
an eighth transistor;
a third pass gate; and
a forth pass gate,
wherein the sixth transistor has a gate connected to the first comparator,
wherein the seventh transistor has a gate for accepting an OR-operated result of the first and the second operator data;
wherein the eighth transistor is connected to the match line, the third and the forth pass gates, and has a gate for accepting an inverted output of the first comparator;
wherein the third pass gate is connected to the complementary search line and the eighth transistor, and has a gate for receiving the first operator data; and
wherein the forth pass gate is connected to the search line and the eighth transistor, and has a gate for receiving the second operator data.

10. A Content Addressable Memory (CAM) comprising:
a match line;
a word line;
N pairs of bit lines and complementary bit lines arranged in the column direction;
N pairs of search lines and complementary search lines;
N range-matching cells connected to the match line, the word line and each of the N pairs of the bit lines,
wherein each range-matching cell includes:
a memory cell, connected to the word line and the bit lines, for storing data transmitted via the bit lines when the word line is activated;
a first transistor connected in series to the match line;
a first comparator connected to the memory cell, the match line and the search lines for controlling turning on or off the first transistor in response to the stored data in the memory cell and searched data transmitted via the search lines; and
a second comparator for connecting the match line to a ground voltage or a predetermined voltage based on the searched data and a stored operator data when the first transistor is turned off, wherein the operator data including logic values of 0 and 1.

11. The CAM of claim 10, wherein one end of the match line is connected to a ground voltage and the other end of the match line is connected to the match line.

12. The CAM of claim 10, wherein the memory cell includes:
storing means for storing the data; and
connecting means for coupling the bit lines to the storing means in order to provide the stored data received by the bit lines to the storing means.

13. The CAM of claim 12, wherein the storing means includes a cross-coupled inverter.

14. The CAM of claim 12, wherein connecting means includes a first and a second pass gate, and the first and the second pass gates are connected to the word line.

15. The CAM of claim 10, wherein the first comparator turns on the first transistor if the stored data matches the searched data, and, if not, turns off the first transistor.

16. The CAM of claim 10, wherein the second comparator connects the match line to the ground voltage if the searched data matches the operator data, and, if not, the second comparator connects the match line to the predetermined voltage.

17. The CAM of claim 12, wherein the first comparator is provided with a second transistor for connecting the search line to the first transistor, the second transistor having a gate connected to the storing means.

18. The CAM of claim 10, wherein the second comparator includes a third, a fourth and a fifth transistor for connecting the match line in series to the ground voltage, wherein the third transistor connects the match line to the fourth transistor, and has a gate connected to the first comparator;
wherein the fourth transistor connects the third transistor to the fifth transistor, and has a gate connected to the search line; and
wherein the fifth transistor connects the fourth transistor to the ground voltage, and has a gate for receiving the operator data.

19. The CAM of claim 10, wherein the second comparator includes:
a sixth and a seventh transistor for connecting the predetermined voltage in series to the match line;
an eighth transistor;
a third pass gate; and
a forth pass gate,
wherein the sixth transistor has a gate connected to the first comparator,
wherein the seventh transistor has a gate for accepting an OR-operated result of the first and the second operator data;
wherein the eighth transistor is connected to the match line, the third and the forth pass gates, and has a gate for accepting an inverted output of the first comparator;
wherein the third pass gate is connected to the complementary search line and the eighth transistor, and has a gate for receiving the first operator data; and
wherein the forth pass gate is connected to the search line and the eighth transistor, and has a gate for receiving the second operator data.
